(19) United States
(12) Patent Application Publication
(10) Pub. No.: US 2015/0255124 A1
(43) Pub. Date: Sep. 10, 2015

(54) ELECTRICALLY ERASABLE PROGRAMMABLE READ-ONLY MEMORY AND STORAGE ARRAY OF THE SAME

(71) Applicant: Shanghai Huahong Grace Semiconductor Manufacturing Corporation, Shanghai (CN)

(72) Inventors: Jing GU, Shanghai (CN); Weiran KONG, Shanghai (CN); Bo ZHANG, Shanghai (CN); Xiong ZHANG, Shanghai (CN); Binghan LI, Shanghai (CN)

(73) Assignee: Shanghai Huahong Grace Semiconductor Manufacturing Corporation, Shanghai (CN)

(21) Appl. No.: 14/584,246

(22) Filed: Dec. 29, 2014

(30) Foreign Application Priority Data
Mar. 5, 2014 (CN) 201410078700.2

(51) Int. Cl. G11C 5/06; G11C 16/14; G11C 16/26; G11C 16/08

(52) U.S. Cl. CPC G11C 5/06; G11C 16/08; G11C 16/14; G11C 16/26

(57) ABSTRACT

An Electrically Erasable Programmable Read-Only Memory (EEPROM) and an EEPROM storage array are provided. The EEPROM storage array includes: at least one storage area, wherein the storage area comprises M word lines in a row direction, 8 bit lines in a column direction, 8 source lines in the column direction, and a plurality of storage units arranged in M rows and 8 columns, where M is a positive integer; and wherein gate electrodes of storage units in a same row are connected with a same word line, drain electrodes of storage units in a same column are connected with a same bit line, and source electrodes of storage units in a same column are connected with a same source line. The EEPROM's volume is reduced by connecting source electrodes of storage units in a same column to a same source line, and arranging the source lines in a column direction.

### CROSS-REFERENCE TO RELATED APPLICATIONS

The present application claims priority to Chinese patent application No. 201410078700.2, filed on Mar. 5, 2014, and entitled “ELECTRICALLY ERASABLE PROGRAMMABLE READ-ONLY MEMORY AND STORAGE ARRAY OF THE SAME”, the entire disclosure of which is incorporated herein by reference.

### TECHNICAL FIELD

The present disclosure generally relates to memory technology, and more particularly, to an Electrically Erasable Programmable Read-Only Memory (EEPROM) and an EEPROM storage array.

### BACKGROUND

Electrically Erasable Programmable Read-Only Memories (EEPROMs) are a kind of semiconductor memory device which has a minimum operation unit of byte, and can be electrically written repeatedly. Compared with Erasable Programmable Read-Only Memories (EPROM), information of the EEPROMs can be erased through a specific voltage without ultraviolet irradiation and dismantling, so that new data can be written. Because of excellent performances and conveniences for online operations, the EEPROMs are widely used in BIOS chips and flash memory chips which are erased frequently, and are gradually replacing parts of Random Access Memories (RAM), which have to retain data in power-off time, and even parts of hard disks. The EEPROMs and high-speed RAMs have been two most popular and fastest-growing storage technologies of the twenty-first century.

An EEPROM usually includes a decoding circuit, a control circuit and a storage array. The storage array of the EEPROM includes a plurality of storage units arranged in rows and columns. FIG. 1 illustrates a cross-sectional diagram of two adjacent storage units in a conventional EEPROM storage array. Referring to FIG. 1, each storage unit includes a substrate 10, a source electrode 11, a drain electrode 12, a floating gate FG and a gate electrode. Specifically, the source electrode 11 and the drain electrode 12 are formed in the substrate 10, the source electrode 11 is connected with a source line SL on a surface of the substrate 10, the drain electrode 12 is connected with a bit line SL on the surface of the substrate 10, the gate electrode is disposed between the source line SL and the bit line BL and is connected with the word line WL, and the floating gate FG is disposed on a part of the surface of the substrate 10 between the word line WL connected with the gate electrode and the source line SL connected with the source electrode 11.

With development of the semiconductor technology to miniaturization and high integration, layout sizes of memory circuits are becoming smaller in order to introduce storage units having high package density into semiconductor memory devices. Even though high-density assembly is imperative, shrinkage of the whole or a part of the storage unit structure shown in FIG. 1 may cause a variety of problems. Therefore, how to reduce the volume of the conventional EEPROM becomes a serious problem.

### SUMMARY

The present disclosure aims to reduce the volume of the conventional EEPROM.

An EEPROM storage array is provided in embodiments of the present disclosure. In one embodiment, the EEPROM includes: at least one storage area, wherein the storage area includes M word lines in a row direction, 8 bit lines in a column direction, 8 source lines in the column direction, and a plurality of storage units arranged in M rows and 8 columns, where M is a positive integer; wherein each storage unit includes a gate electrode, a drain electrode and a source electrode; and wherein gate electrodes of storage units in a same row are connected with a same word line, drain electrodes of storage units in a same column are connected with a same bit line, and source electrodes of storage units in a same column are connected with a same source line.

In some embodiments, storage units in the m^{th} row and the (m+1)^{th} row, which are arranged in a same column, share a same source electrode, storage units in the m^{th} row and the (m−1)^{th} row, which are arranged in a same column, share a same drain electrode, 1≦m≦M, and m is an odd number.

In some embodiments, drain electrodes of storage units in a same column are connected with a same bit line through contact holes which are filled with conductive material, and source electrodes of storage units in a same column are connected with a same source line through contact holes which are filled with conductive material.

In some embodiments, when a reading operation is performed on a storage unit to be read in the storage area, a voltage applied to a word line connected with the storage unit to be read ranges from 1.5 V to 3.3 V, a voltage applied to a bit line connected with the storage unit to be read ranges from 0.5 V to 1.5 V, and a voltage applied to a source line connected with the storage unit to be read is 0 V.

In some embodiments, when a programming operation is performed on a storage unit to be programmed in the storage area, a voltage applied to a word line connected with the storage unit to be programmed ranges from −10 V to −6 V, a voltage applied to a bit line connected with the storage unit to be programmed ranges from 0 V to 2 V, and a voltage applied to a source line connected with the storage unit to be programmed ranges from 3 V to 8 V.

In some embodiments, when an erasing operation is performed on a storage unit to be erased in the storage area, a voltage applied to a word line connected with the storage unit to be erased ranges from 10 V to 13 V, a voltage applied to a bit line connected with the storage unit to be erased is 0 V, and a voltage applied to a source line connected with the storage unit to be erased is 0 V.

In some embodiments, the storage unit further includes a substrate and a floating gate, the drain electrode and the source electrode is disposed in the substrate, and the floating gate is disposed on a surface of the substrate between the word line connected with the gate electrode and the bit line connected with the source electrode.

Based on the above EEPROM storage array, an EEPROM is provided in embodiments of the present disclosure. The EEPROM includes a decoding circuit, a control circuit and at least one EEPROM storage array described above.

Compared with the conventional technology, embodiments of the present disclosure have following advantages.

In the EEPROM storage array of the present disclosure, a number of the source lines is reduced by connecting source electrodes of storage units in a same column to a same source line, and arranging the source lines in a column direction. The reduction of the number of the source lines can reduce a volume of the decoding circuit of the EEPROM and a volume of the EEPROM. Moreover, source lines of the EEPROM storage array provided in the present disclosure are arranged in a column direction. Compared with conventional EEPROM storage arrays formed by same processes, storage units of the EEPROM storage array of the present disclosure have larger active areas which can improve performance of the EEPROM storage array.

### BRIEF DESCRIPTION OF THE DRAWINGS

FIG. 1 illustrates a cross-sectional structure diagram of two adjacent storage units in a conventional EEPROM storage array;

FIG. 2 illustrates a circuit diagram of a storage area according to one embodiment of the present disclosure;

FIG. 3 illustrates a layout diagram of the storage area according to one embodiment of the present disclosure;

FIG. 4 illustrates a layout diagram when a reading operation is performed on a storage unit of the storage array according to one embodiment of the present disclosure;

FIG. 5 illustrates a layout diagram when a programming operation is performed on a storage unit of the storage array according to one embodiment of the present disclosure; and

FIG. 6 illustrates a layout diagram when an erasing operation is performed on a storage unit of the storage array according to one embodiment of the present disclosure.

### DETAILED DESCRIPTION

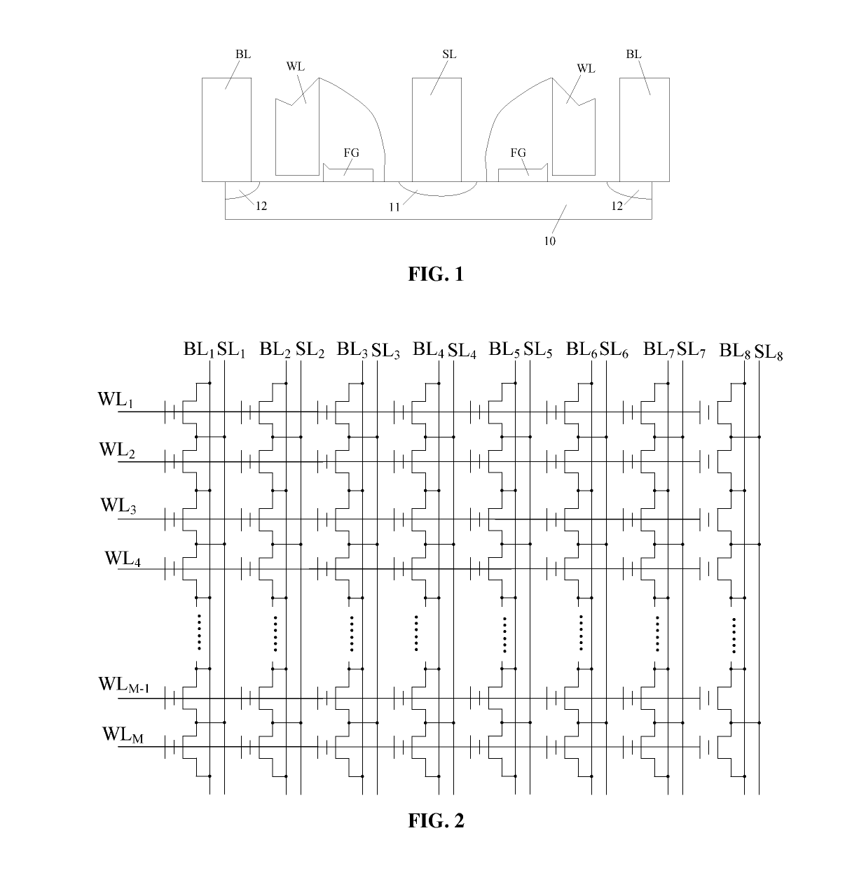

As described above, in order to ensure performance of the EEPROM, the whole or a part of the storage unit structure shown in FIG. 1 cannot be shrunken. In the prior art, a Hot Carrier Injection (HCI) method is usually used to program and erase an EEPROM storage array constituted by the storage units shown in FIG. 1. That is, there is a need to apply a high voltage to the source line SL connected with the source electrode 11. Because the source line SL needs to withstand the high voltage, manufacturing processes limits the source line SL to be arranged in a row direction. That is, source electrodes of storage units in a same row are connected with a same source line.

An EEPROM storage array is provided in embodiments of the present disclosure. Operation methods of the EEPROM is changed, so that source electrodes of storage units in a same column can be connected with a same source line, and sources lines can be arranged in a column direction to reduce a number of the source lines. Therefore, a volume of a decoding circuit of the EEPROM can be reduced, and then a volume of the EEPROM can be reduced.

In order to clarify the objects, characteristics and advantages of the disclosure, the embodiments of the present disclosure will be described in detail in conjunction with the accompanying drawings.

An EEPROM storage array is provided in embodiments of the present disclosure. The EEPROM storage array includes at least one storage area. FIG. 2 illustrates a circuit diagram of the storage area according to one embodiment of the present disclosure. Referring to FIG. 2, the storage area includes M word lines (WL₁, WL₂, WL₃, WL₄, . . . , WL_{M-1}, WL_{M}) in a row direction, 8 bit lines (BL₁, BL₂, BL₃, BL₄, BL₅, BL₆, BL₇, BL₈) in a column direction, 8 source lines (SL₁, SL₂, SL₃, SL₄, SL₅, SL₆, SL₇, SL₈) in the column direction, and a plurality of storage units arranged in M rows and 8 columns, wherein M is a positive integer.

The structure of the storage unit is similar to the structure of the storage unit shown in FIG. 1. The storage unit includes a substrate, a source electrode, a drain electrode, a gate electrode and a floating gate. The source electrode and the drain electrode are formed in the substrate, the source electrode is connected with a source line on a surface of the substrate, the drain electrode is connected with a bit line on the surface of the substrate, the gate electrode is disposed between the source line and the bit line and is connected with the word line, and the floating gate is disposed on a part of the surface of the substrate between the word line connected with the gate electrode and the bit line connected with the source electrode.

Specifically, in the storage area, gate electrodes of storage units in a same row are connected with a same word line. That is, gate electrodes of storage units in the first row are connected with a word line WL₁, gate electrodes of storage units in the second row are connected with a word line WL₂, gate electrodes of storage units in the third row are connected with a word line WL₃, gate electrodes of storage units in the fourth row are connected with a word line WL₄, . . . , gate electrodes of storage units in the (M−1)^{th} row are connected with a word line WL_{M-1}, and gate electrodes of storage units in the M^{th} row are connected with a word line WL_{M}.

Drain electrodes of storage units in a same column are connected with a same bit line. That is, drain electrode of storage units in the first column are connected with a bit line BL₁, drain electrode of storage units in the second column are connected with a bit line BL₂, drain electrode of storage units in the third column are connected with a bit line BL₃, drain electrode of storage units in the fourth column are connected with a bit line BL₄, drain electrode of storage units in the fifth column are connected with a bit line BL₅, drain electrode of storage units in the sixth column are connected with a bit line BL₆, drain electrode of storage units in the seventh column are connected with a bit line BL₇, and drain electrode of storage units in the eighth column are connected with a bit line BL₈.

Source electrodes of storage units in a same column are connected with a same source line. That is, source electrodes of storage units in the first column is connected with a source line SL₁, source electrodes of storage units in the second column is connected with a source line SL₂, source electrodes of storage units in the third column is connected with a source line SL₃, source electrodes of storage units in the fourth column is connected with a source line SL₄, source electrodes of storage units in the fifth column is connected with a source line SL₅, source electrodes of storage units in the sixth column is connected with a source line SL₆, source electrodes of storage units in the seventh column is connected with a source line SL₇, and source electrodes of storage units in the eighth column is connected with a source line SL₈.

Storage units in the m^{th} row and the (m+1)^{th} row, which are arranged in a same column, share a same source electrode, and storage units in the m^{th} row and the (m−1)^{th} row, which are arranged in a same column, share a same drain electrode, wherein m is an odd number, and 1≦m≦M. Specifically, for the storage units in a same column, a storage unit in the first row and a storage unit in the second row share a source electrode, a storage unit in the second row and a storage unit in the third row share a drain electrode, a storage unit in the third row and a storage unit in the fourth row share a source electrode, . . . , a storage unit in the (M−1)^{th} row and a storage unit in the M^{th} row share a source electrode.

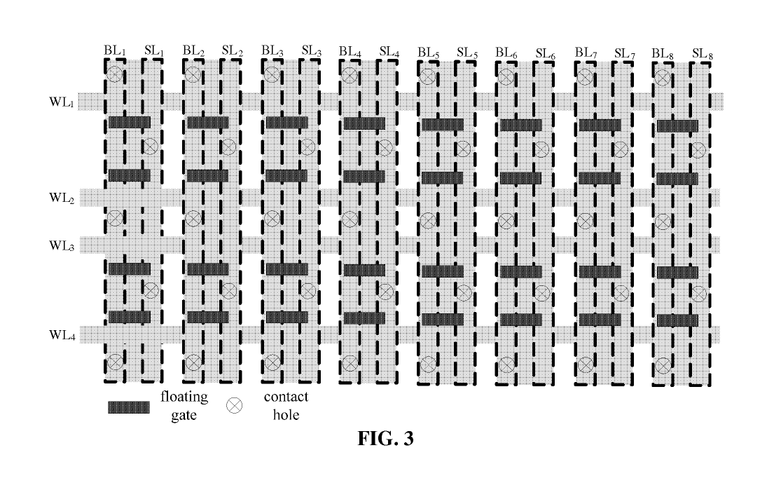

Taking M=4 as an example, a layout diagram of the storage area is illustrated in FIG. 3 according to one embodiment of the present disclosure. Referring to FIG. 3, in the storage area, drain electrodes of storage units in a same column are connected to a same bit line through contact holes which are filled with conductive material, and source electrodes of storage units in a same column are connected with a same source line through contact holes which are filled with conductive material.

In order to clarify reading, programming and erasing operations of the EEPROM storage array, the embodiments of the present disclosure will be described in detail in conjunction with Table 1 and the accompanying drawings.

TABLE 1

| | Word Line | Bit Line | Source Line |
|---|---|---|---|
| Reading | 1.5 V to 3.3 V | 0.5 V to 1.5 V | 0 V |
| Programming | −10 V to −6 V | 0 V to 2 V | 3 V to 8 V |
| Erasing | 10 V to 13 V | 0 V | 0 V |

When a reading operation is performed on a storage unit to be read in the storage area, a voltage applied to a word line connected with the storage unit to be read ranges from 1.5 V to 3.3 V, a voltage applied to a bit line connected with the storage unit to be read ranges from 0.5 V to 1.5 V, and a voltage applied to a source line connected with the storage unit to be read is 0 V. The storage unit to be read is turned on by applying the above reading voltages, and a current is read out from the bit line connected with the storage unit to complete the reading operation.

When a programming operation is performed on a storage unit to be programmed in the storage area, a voltage applied to a word line connected with the storage unit to be programmed ranges from −10 V to −6 V, a voltage applied to a bit line connected with the storage unit to be programmed ranges from 0 V to 2 V, and a voltage applied to a source line connected with the storage unit to be programmed ranges from 3 V to 8 V. By applying the above programming voltages, the voltage applied to the source line is coupled with the floating gate of the storage unit to be programmed. Then, under an effect of an electric field between the word line and the floating gate, electrons from the word line are injected into to the floating gate, so that the programming operation is achieved.

When an erasing operation is performed on a storage unit to be erased in the storage area, a voltage applied to a word line connected with the storage unit to be erased ranges from 10 V to 13 V, a voltage applied to a bit line connected with the storage unit to be erased is 0 V, and a voltage applied to a source line connected with the storage unit to be erased is 0 V. By applying the above erasing voltages, electrons stored in the floating gate of the storage unit to be erased flow away through the word line, so that the erasing operation is achieved.

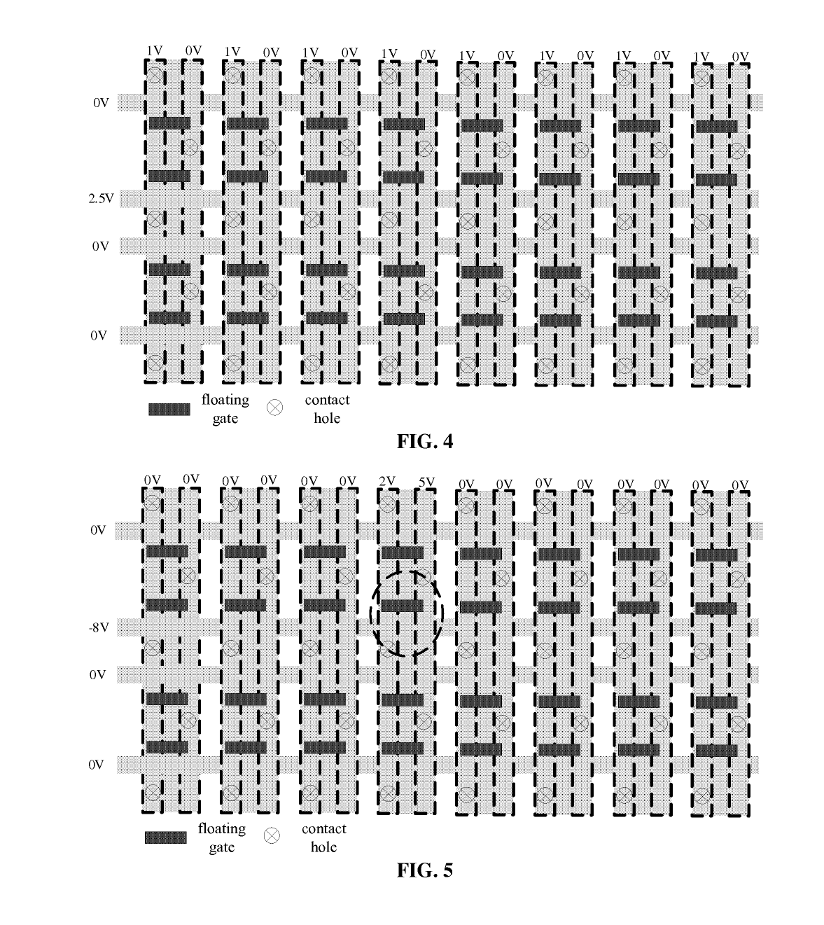

FIG. 4 illustrates a layout diagram of a reading operation performed on storage units in the second row of the storage array shown in FIG. 3. Referring to FIG. 4, in this embodiment, when a reading operation is performed on the storage units in the second row of the storage array shown in FIG. 3, a 2.5 V voltage is applied to the word line WL₂, a 0 V voltage is applied to the word line WL₁, the word line WL₃ and the word line WL₄, a 1 V voltage is applied to the bit lines BL₁˜BL₈, and a 0 V voltage is applied to the source lines SL₁˜SL₈.

FIG. 5 illustrates a layout diagram of a programming operation performed on a storage unit in the second row and the fourth column of the storage array shown in FIG. 3. Referring to FIG. 5, in this embodiment, when a programming operation is performed on the storage unit in the second row and the fourth column of the storage array shown in FIG. 3, a −8 V voltage is applied to the word line WL₂, a 0 V voltage is applied to the word line WL₁, the Word line WL₃ and the word line WL₄, a 2 V voltage is applied to the bit line BL₄, a 0 V voltage is applied to the other bit lines, a 5 V voltage is applied to the source line SL₄, and a 0 V voltage is applied to the other source lines.

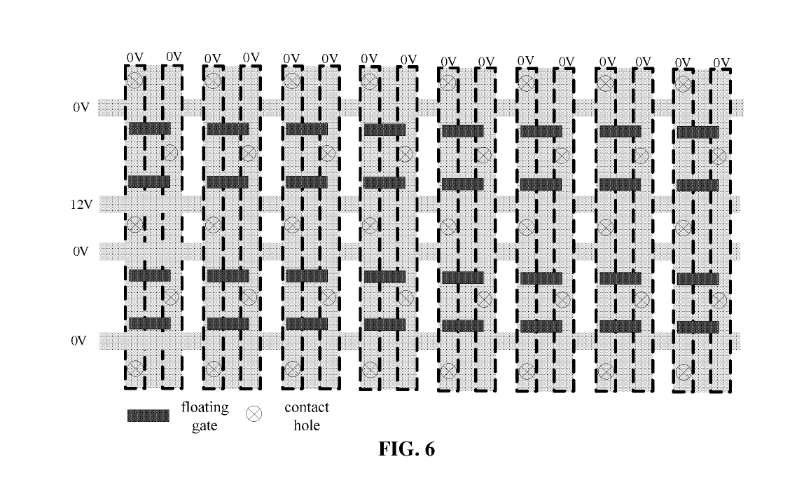

FIG. 6 illustrates a layout diagram of an erasing operation performed on storage units in the second row of the storage array shown in FIG. 3. Referring to FIG. 6, in this embodiment, when an erasing operation is performed on the storage units in the second row of the storage array shown in FIG. 3, an 12 V voltage is applied to the word line WL₂, a 0 V voltage is applied to the word line WL₁, the word line WL₃ and the word line WL₄, a 0 V voltage is applied to the bit lines BL₁˜BL₈, and a 0 V voltage is applied to the source lines SL₁˜SL₈.

In an EEPROM storage array constituted by storage units, a number of rows is far greater than a number of columns. In this embodiment, the row number M of storage units of the storage area is far greater than the column number 8. Therefore, compared with the conventional EEPROM storage array which arranges the source lines in a row direction, a number of the source lines is reduced by connecting source electrodes of storage units in a same column to a same source line, and arranging the source lines in a column direction. The reduction of the number of the source lines can reduce a volume of the decoding circuit of the EEPROM and a volume of the EEPROM.

Moreover, source lines of the EEPROM storage array provided in the present disclosure are arranged in a column direction. Compared with conventional EEPROM storage arrays formed by same processes, storage units of the EEPROM storage array of the present disclosure have larger active areas which can improve performance of the EEPROM storage array.

According to the above EEPROM storage array, an EEPROM device is provided in embodiments of the present disclosure. The EEPROM may include a decoding circuit, a control circuit and an EEPROM storage array, wherein the EERPOM may be constituted by the storage area shown in FIG. 2.

In conclusion, according to the EEPROM storage array and the EEPROM provided in embodiments of the present disclosure, the volume of the EEPROM is reduced by connecting source electrodes of storage units in a same column to a same source line, and arranging the source lines in a column direction.

Although the present disclosure has been disclosed above with reference to preferred embodiments thereof, it should be understood by those skilled in the art that various changes may be made without departing from the spirit or scope of the disclosure. Accordingly, the present disclosure is not limited to the embodiments disclosed.

What is claimed is:

1. An Electrically Erasable Programmable Read-Only Memory (EEPROM) storage array, comprising: at least one storage area,
wherein the storage area comprises M word lines in a row direction, 8 bit lines in a column direction, 8 source lines in the column direction, and a plurality of storage units arranged in M rows and 8 columns, where M is a positive integer;
wherein each storage unit comprises a gate electrode, a drain electrode and a source electrode; and
wherein gate electrodes of storage units in a same row are connected with a same word line, drain electrodes of storage units in a same column are connected with a same bit line, and source electrodes of storage units in a same column are connected with a same source line.

2. The EEPROM storage array according to claim 1, wherein storage units in the m^{th} row and the (m+1)^{th} row, which are arranged in a same column, share a same source electrode, storage units in the m^{th} row and the (m−1)^{th} row, which are arranged in a same column, share a same drain electrode, 1≦m≦M, and m is an odd number.

3. The EEPROM storage array according to claim 1, wherein drain electrodes of storage units in a same column are connected with a same bit line through contact holes which are filled with conductive material, and source electrodes of storage units in a same column are connected with a same source line through contact holes which are filled with conductive material.

4. The EEPROM storage array according to claim 1, wherein when a reading operation is performed on a storage unit to be read in the storage area, a voltage applied to a word line connected with the storage unit to be read ranges from 1.5 V to 3.3 V, a voltage applied to a bit line connected with the storage unit to be read ranges from 0.5 V to 1.5 V, and a voltage applied to a source line connected with the storage unit to be read is 0 V.

5. The EEPROM storage array according to claim 2, wherein when a reading operation is performed on a storage unit to be read in the storage area, a voltage applied to a word line connected with the storage unit to be read ranges from 1.5 V to 3.3 V, a voltage applied to a bit line connected with the storage unit to be read ranges from 0.5 V to 1.5 V, and a voltage applied to a source line connected with the storage unit to be read is 0 V.

6. The EEPROM storage array according to claim 3, wherein when a reading operation is performed on a storage unit to be read in the storage area, a voltage applied to a word line connected with the storage unit to be read ranges from 1.5 V to 3.3 V, a voltage applied to a bit line connected with the storage unit to be read ranges from 0.5 V to 1.5 V, and a voltage applied to a source line connected with the storage unit to be read is 0 V.

7. The EEPROM storage array according to claim 1, wherein when a programming operation is performed on a storage unit to be programmed in the storage area, a voltage applied to a word line connected with the storage unit to be programmed ranges from −10 V to −6 V, a voltage applied to a bit line connected with the storage unit to be programmed ranges from 0 V to 2 V, and a voltage applied to a source line connected with the storage unit to be programmed ranges from 3 V to 8 V.

8. The EEPROM storage array according to claim 2, wherein when a programming operation is performed on a storage unit to be programmed in the storage area, a voltage applied to a word line connected with the storage unit to be programmed ranges from −10 V to −6 V, a voltage applied to a bit line connected with the storage unit to be programmed ranges from 0 V to 2 V, and a voltage applied to a source line connected with the storage unit to be programmed ranges from 3 V to 8 V.

9. The EEPROM storage array according to claim 3, wherein when a programming operation is performed on a storage unit to be programmed in the storage area, a voltage applied to a word line connected with the storage unit to be programmed ranges from −10 V to −6 V, a voltage applied to a bit line connected with the storage unit to be programmed ranges from 0 V to 2 V, and a voltage applied to a source line connected with the storage unit to be programmed ranges from 3 V to 8 V.

10. The EEPROM storage array according to claim 1, wherein when an erasing operation is performed on a storage unit to be erased in the storage area, a voltage applied to a word line connected with the storage unit to be erased ranges from 10 V to 13 V, a voltage applied to a bit line connected with the storage unit to be erased is 0 V, and a voltage applied to a source line connected with the storage unit to be erased is 0 V.

11. The EEPROM storage array according to claim 2, wherein when an erasing operation is performed on a storage unit to be erased in the storage area, a voltage applied to a word line connected with the storage unit to be erased ranges from 10 V to 13 V, a voltage applied to a bit line connected with the storage unit to be erased is 0 V, and a voltage applied to a source line connected with the storage unit to be erased is 0 V.

12. The EEPROM storage array according to claim 3, wherein when an erasing operation is performed on a storage unit to be erased in the storage area, a voltage applied to a word line connected with the storage unit to be erased ranges from 10 V to 13 V, a voltage applied to a bit line connected with the storage unit to be erased is 0 V, and a voltage applied to a source line connected with the storage unit to be erased is 0 V.

13. The EEPROM storage array according to claim 1, wherein the storage unit further comprises a substrate and a floating gate, the drain electrode and the source electrode is disposed in the substrate, and the floating gate is disposed on a surface of the substrate between the word line connected with the gate electrode and the bit line connected with the source electrode.

14. An Electrically Erasable Programmable Read-Only Memory (EEPROM), comprising: a decoding circuit, a control circuit and at least one EEPROM storage array,
wherein the storage area comprises M word lines in a row direction, 8 bit lines in a column direction, 8 source lines in the column direction, and a plurality of storage units arranged in M rows and 8 columns, where M is a positive integer;
wherein each storage unit comprises a gate electrode, a drain electrode and a source electrode; and
wherein gate electrodes of storage units in a same row are connected with a same word line, drain electrodes of storage units in a same column are connected with a same bit line, and source electrodes of storage units in a same column are connected with a same source line.

15. The EEPROM according to claim 14, wherein storage units in the m^{th} row and the (m+1)^{th} row, which are arranged in a same column, share a same source electrode, storage units in the m^{th} row and the (m−1)^{th} row, which are arranged in a same column, share a same drain electrode, 1≦m≦M, and m is an odd number.

16. The EEPROM according to claim 14, wherein drain electrodes of storage units in a same column are connected with a same bit line through contact holes which are filled with conductive material, and source electrodes of storage units in a same column are connected with a same source line through contact holes which are filled with conductive material.

17. The EEPROM according to claim 14, wherein when a reading operation is performed on a storage unit to be read in the storage area, a voltage applied to a word line connected with the storage unit to be read ranges from 1.5 V to 3.3 V, a voltage applied to a bit line connected with the storage unit to be read ranges from 0.5 V to 1.5 V, and a voltage applied to a source line connected with the storage unit to be read is 0 V.

18. The EEPROM according to claim 14, wherein when a programming operation is performed on a storage unit to be programmed in the storage area, a voltage applied to a word line connected with the storage unit to be programmed ranges from −10 V to −6 V, a voltage applied to a bit line connected with the storage unit to be programmed ranges from 0 V to 2 V, and a voltage applied to a source line connected with the storage unit to be programmed ranges from 3 V to 8 V.

19. The EEPROM according to claim 14, wherein when an erasing operation is performed on a storage unit to be erased in the storage area, a voltage applied to a word line connected with the storage unit to be erased ranges from 10 V to 13 V, a voltage applied to a bit line connected with the storage unit to be erased is 0 V, and a voltage applied to a source line connected with the storage unit to be erased is 0 V.

20. The EEPROM according to claim 14, wherein the storage unit further comprises a substrate and a floating gate, the drain electrode and the source electrode is disposed in the substrate, and the floating gate is disposed on a surface of the substrate between the word line connected with the gate electrode and the bit line connected with the source electrode.
